(19) United States
(12) Patent Application Publication
(10) Pub. No.: US 2026/0280571 A1
(43) Pub. Date: Sep. 17, 2026

(54) SIGNAL GENERATION DEVICE, IMAGING DEVICE, AND ELECTRONIC APPARATUS

(71) Applicant: Sony Semiconductor Solutions Corporation, Kanagawa (JP)

(72) Inventors: Zhiwei Zhou, Tokyo (JP); Junya Akaike, Kanagawa (JP)

(21) Appl. No.: 19/471,629

(22) PCT Filed: Apr. 30, 2024
(86) PCT No.: PCT/JP2024/016648

§ 371 Date: Oct. 1, 2025

(30) Foreign Application Priority Data
May 17, 2023 (JP) 2023-081566

(51) Int. Cl. H03L 7/099; H03L 7/093; H04N 25/76

(52) U.S. Cl. CPC H03L 7/0992; H03L 7/093; H04N 25/7795

(57) ABSTRACT

Provided is a signal generation device including: a digitally controlled oscillator, a first path including a phase-locked loop that detects a phase error between an output of the digitally controlled oscillator and a reference signal and performs feedback control of the digitally controlled oscillator via a loop filter, a second path that controls the digitally controlled oscillator based on the reference signal without passing through the loop filter, and a first calibration unit that performs calibration in real time on the digitally controlled oscillator based on a correlation between the phase error and a waveform of the reference signal.

### FIELD

The present disclosure relates to a signal generation device, an imaging device, and an electronic apparatus.

### BACKGROUND

A signal generation device is mounted, for example, on an electronic apparatus such as an imaging device (image sensor). A clock signal supplied by the signal generation device is supplied to, for example, a signal processing unit that performs AD conversion processing in the imaging device.

### CITATION LIST

### Patent Literature

Patent Literature 1: JP 2011-503983 A

### SUMMARY

### Technical Problem

However, a signal generation device according to the prior art has a mechanism for performing one-time calibration at the time of starting the signal generation device, but when there is a fluctuation in temperature, power supply voltage, or the like, there is a case where an output signal from the signal generation device does not satisfy required specifications (specs).

Therefore, the present disclosure proposes a signal generation device capable of satisfying required specifications for an output signal even when there is a fluctuation in temperature, power supply voltage, or the like, and an imaging device and an electronic apparatus equipped with the signal generation device.

### Solution to Problem

According to the present disclosure, there is provided a signal generation device including: a digitally controlled oscillator; a first path including a phase-locked loop that detects a phase error between an output of the digitally controlled oscillator and a reference signal, and performs feedback control of the digitally controlled oscillator via a loop filter; a second path that controls the digitally controlled oscillator based on the reference signal without passing through the loop filter; and a first calibration unit that performs calibration in real time on the digitally controlled oscillator based on a correlation between the phase error and a waveform of the reference signal.

Furthermore, according to the present disclosure, there is provided an imaging device including: a plurality of imaging elements that detect light; a signal processing unit that performs processing on an output signal from the plurality of imaging elements; a control unit that controls the plurality of imaging elements; and a signal generation device that outputs a reference clock signal to the signal processing unit and the control unit. In the imaging device, the signal generation device includes: a digitally controlled oscillator; a first path including a phase-locked loop that detects a phase error between an output of the digitally controlled oscillator and a reference signal, and performs feedback control of the digitally controlled oscillator via a loop filter; a second path that controls the digitally controlled oscillator based on the reference signal without passing through the loop filter; and a first calibration unit that performs calibration in real time on the digitally controlled oscillator based on a correlation between the phase error and a waveform of the reference signal.

Furthermore, according to the present disclosure, there is provided an electronic apparatus provided with a signal generation device. In the electronic apparatus, the signal generation device includes: a digitally controlled oscillator; a first path including a phase-locked loop that detects a phase error between an output of the digitally controlled oscillator and a reference signal, and performs feedback control of the digitally controlled oscillator via a loop filter; a second path that controls the digitally controlled oscillator based on the reference signal without passing through the loop filter; and a first calibration unit that performs calibration in real time on the digitally controlled oscillator based on a correlation between the phase error and a waveform of the reference signal.

### BRIEF DESCRIPTION OF DRAWINGS

FIG. 1 is a diagram illustrating a circuit configuration of a signal generation device 10a according to a comparative example.

FIG. 2 is a diagram illustrating a circuit configuration of a signal generation device 10b according to a comparative example.

FIG. 3 is a diagram (Part 1) illustrating the operation of the signal generation device 10b according to the comparative example.

FIG. 4 is a diagram (Part 2) illustrating the operation of the signal generation device 10b according to the comparative example.

FIG. 5 is a diagram illustrating a circuit configuration of a signal generation device 10 according to an embodiment of the present disclosure.

FIG. 6 is a diagram illustrating an operation of the signal generation device 10 according to the embodiment of the present disclosure.

FIG. 7 is a diagram illustrating a signal generated by the signal generation device 10 according to the embodiment of the present disclosure.

FIG. 8 is a diagram illustrating a circuit configuration of a calibration unit 130 according to the embodiment of the present disclosure.

FIG. 9 is a diagram illustrating a circuit configuration of a calibration unit 130a according to a modification of the embodiment of the present disclosure.

FIG. 10 is a diagram illustrating a circuit configuration of a calibration unit 130b according to a modification of the embodiment of the present disclosure.

FIG. 11 is a diagram illustrating a circuit configuration of a calibration unit 130c according to a modification of the embodiment of the present disclosure.

FIG. 12 is a diagram illustrating a circuit configuration of a calibration unit 130d according to a modification of the embodiment of the present disclosure.

FIG. 13 is a diagram illustrating a circuit configuration of a calibration unit 130e according to a modification of the embodiment of the present disclosure.

FIG. 14 is a diagram illustrating an example of a schematic configuration of an imaging device 3 to which the signal generation device 10 according to the embodiment of the present disclosure can be applied.

FIG. 15 is an explanatory diagram illustrating an example of a schematic functional configuration of a camera 700 to which the technology according to the present disclosure (present technology) can be applied.

FIG. 16 is a block diagram illustrating an example of a schematic functional configuration of a smartphone 900 to which the technology according to the present disclosure (present technology) can be applied.

### DESCRIPTION OF EMBODIMENTS

Hereinafter, preferred embodiments of the present disclosure will be described in detail with reference to the accompanying drawings. Note that, in the present specification and the drawings, components having substantially the same functional configuration are denoted by the same reference signs to omit redundant description. In addition, in the present specification and the drawings, a plurality of components having substantially the same or similar functional configurations may be distinguished by attaching a different alphabet after the same reference sign. However, when it is not particularly necessary to distinguish each of the plurality of components having substantially the same or similar functional configuration, only the same reference sign is assigned.

Note that the description will be given in the following order.
1. Background
2. Embodiment
3. Modifications
4. Summary
5. Imaging device
6. Electronic apparatus
7. Supplement

### 1. Background

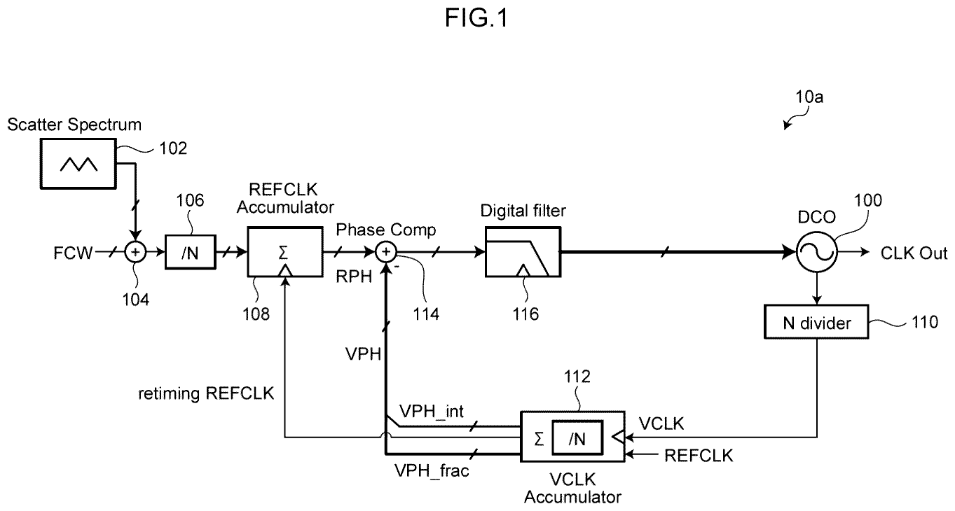

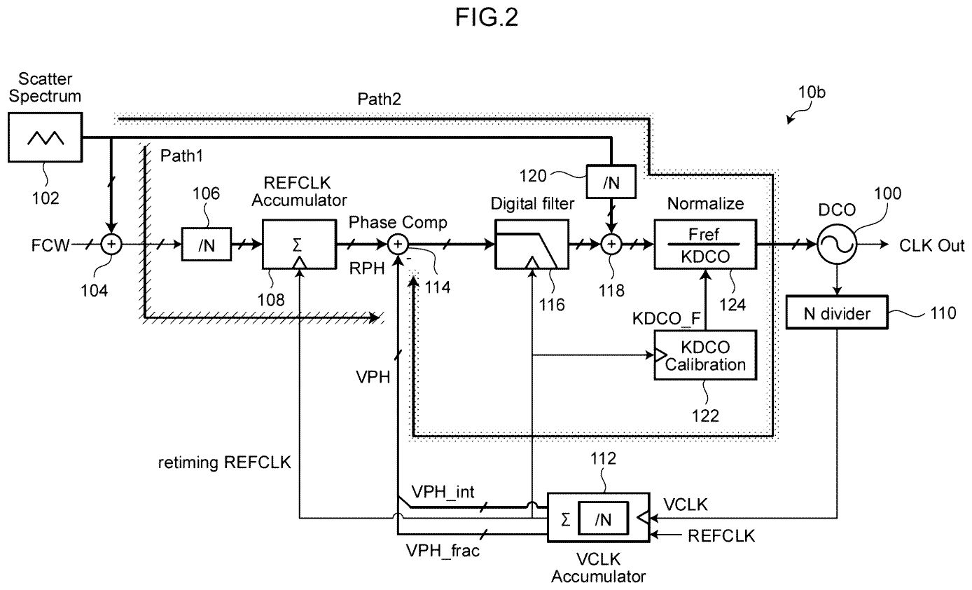

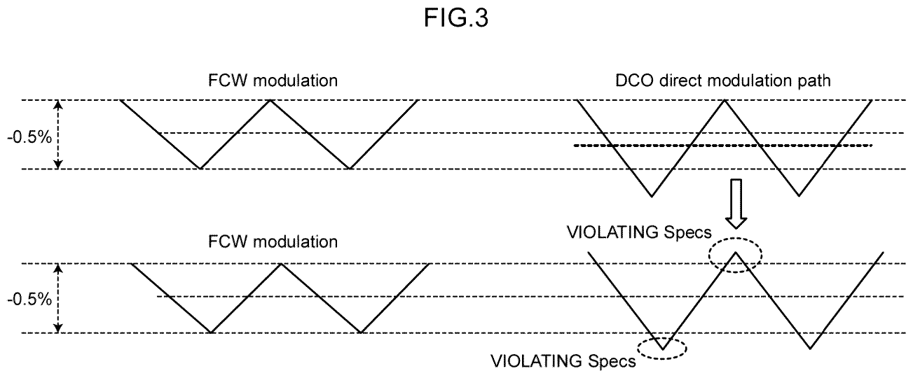

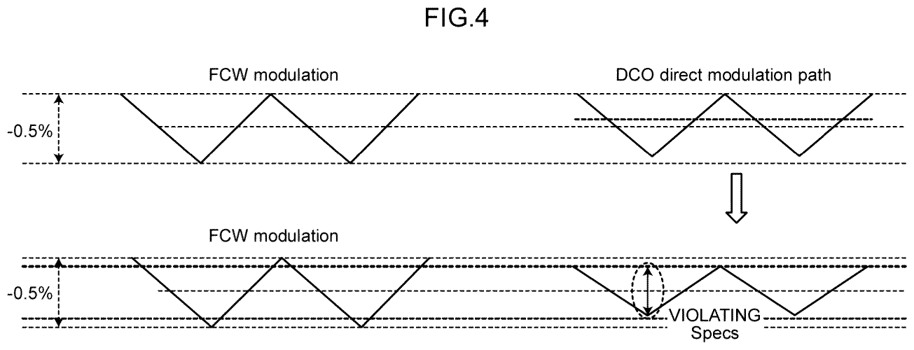

First, before describing details of an embodiment of the present disclosure, the background leading to the creation of the embodiment of the present disclosure by the inventors will be described with reference to FIGS. 1 to 4. FIG. 1 is a diagram illustrating a circuit configuration of a signal generation device 10a according to a comparative example, and FIG. 2 is a diagram illustrating a circuit configuration of a signal generation device 10b according to a comparative example. FIGS. 3 and 4 are diagrams illustrating the operation of the signal generation device 10b according to the comparative example. Note that, here, the comparative examples are the signal generation devices 10a and 10b that the inventors have studied before carrying out the embodiment of the present disclosure.

For example, in an electronic apparatus such as an imaging device, a signal generation device is provided in order to supply a reference clock to a signal processing unit, a control unit, and the like. Such a signal generation device is required to satisfy frequency accuracy within predetermined specifications (specs) even when a power supply voltage, a temperature, or the like fluctuates, and required to stably and quickly supply a signal having a modulation frequency and a modulation width within the specifications (specs) when frequency modulation is performed. Therefore, the signal generation device generally includes a phase-locked loop circuit (PLL circuit). The PLL circuit is a circuit that detects a phase error between an output signal and a reference signal, and configures a loop (closed circuit) so as to eliminate the phase error, thereby synchronizing the output signal with the reference signal. The PLL circuit generally includes a phase comparator that detects a phase error between an output signal of a voltage controlled oscillator and a reference signal, a loop filter that removes noise and outputs a result of the phase error detected to the voltage controlled oscillator to control (modulate) the voltage controlled oscillator, and a frequency divider that frequency-divides the output signal of the voltage controlled oscillator and provides a feedback input to the phase comparator.

First, the inventors have studied the signal generation device 10a having a circuit configuration as illustrated in FIG. 1. The signal generation device 10a according to the comparative example includes a digitally controlled oscillator 100, a phase comparator 114 configuring a phase-locked loop circuit, a digital filter 116, a frequency divider 110, and the like. The digital filter 116 may be required to be designed in a narrow band in order to reduce noise such as noise of the reference signal and noise generated inside. Then, when a spread spectrum clock generator (SSC) is operated and the digital filter 116 is designed to have a narrow band as a measure against an electromagnetic interference (EMI), there is a possibility that a frequency modulated by the SSC exceeds a band of the digital filter 116. Therefore, depending on the frequency, there is a signal whose passage is inhibited by the digital filter 116, and the digitally controlled oscillator 100 cannot be appropriately modulated. As a result, an output signal may be distorted. In other words, in the signal generation device 10a according to the comparative example, the digitally controlled oscillator 100 may not be appropriately modulated by the digital filter.

Therefore, the inventors have studied a two-point signal generation device 10b that performs modulation at two points as illustrated in FIG. 2. The signal generation device 10b illustrated in FIG. 2 has a PLL circuit similarly to the signal generation device 10a, and further has a path capable of directly modulating the digitally controlled oscillator 100 without passing through the digital filter 116. In the two-point signal generation device 10b, by providing such a path, modulation can be performed based on a signal lost by the digital filter 116, so that the digitally controlled oscillator 100 can be appropriately modulated. As a result, distortion of an output signal can be suppressed. Specifically, in the signal generation device 10b illustrated in FIG. 2, modulation can be applied to the digitally controlled oscillator 100 at two different points with the digital filter 116 interposed therebetween by a path restricted by the digital filter 116 and a direct path reaching the digitally controlled oscillator 100 without passing through the digital filter 116. Therefore, in the signal generation device 10b, the digitally controlled oscillator 100 is not restricted by the digital filter 116.

However, in the signal generation device 10b illustrated in FIG. 2, in order to appropriately apply modulation at two different points, a gain needs to be matched between the path restricted by the digital filter 116 and the direct path reaching the digitally controlled oscillator 100 without passing through the digital filter 116. A path 1 from a spread spectrum clock generator (SSC) 102 to the phase comparator 114 illustrated in FIG. 2 is configured by a digital circuit. Thus, the gain can be easily adjusted. On the other hand, a path 2 from the SSC 102 to the digitally controlled oscillator 100 without passing through the digital filter 116 and from the digitally controlled oscillator 100 to the phase comparator 114 via the frequency divider 110 includes an analog circuit. Thus, gain calibration is needed. Therefore, in the two-point signal generation device 10b, one-time calibration is performed at the time of starting the signal generation device 10b. Specifically, a one-time calibration unit 122 generates a gain setting value KDCO_F for adjusting the gain based on an output signal of the digitally controlled oscillator 100, and outputs the gain setting value KDCO_F to a gain normalization unit 124. Based on a phase error output from the digital filter 116, a control value based on modulation by the direct path described above, and the gain setting value KDCO_F, the gain normalization unit 124 generates a control signal for controlling the digitally controlled oscillator 100 based on a modulation sensitivity of the digitally controlled oscillator 100. Then, the gain calibration is performed by modulating the digitally controlled oscillator 100 by the control signal generated. As a result, in the signal generation device 10b, the gain can be matched between the path restricted by the digital filter 116 and the direct path reaching the digitally controlled oscillator 100 without passing through the digital filter 116.

However, as a result of repeated studies by the inventors, even when the above-described one-time calibration is performed, the output signal from the signal generation device 10b may not satisfy the specifications (specs) required as the output signal. Even when the calibration unit 122 can perform appropriate calibration at the time of starting the signal generation device 10b, the output signal will greatly differ from a target state when there is an influence of a fluctuation in temperature, power supply voltage, or the like. Specifically, the calibration unit 122 can calibrate offset (DC) fluctuation (drift) of the output signal to match centers of frequency waveforms at the time of starting the signal generation device 10b. However, the calibration unit 122 cannot appropriately calibrate a modulation width of the frequency when the modulation width of the frequency of the output signal, modulated under the influence of a fluctuation in temperature, power supply voltage, or the like, fluctuates. Therefore, when there is a fluctuation in temperature, power supply voltage, or the like, the output signal of the digitally controlled oscillator 100 may not satisfy the specifications (specs) required as the output signal in the two-point signal generation device 10b.

Furthermore, details of the above-described problem will be described with reference to FIGS. 3 and 4. FIGS. 3 and 4 are diagrams illustrating the operation of the signal generation device 10b according to the comparative example. Specifically, in FIGS. 3 and 4, a frequency waveform of a signal passing through the path 1 is illustrated on the left side, and a frequency waveform of a signal passing through the path 2 and a frequency waveform of a signal after the signal is calibrated by the calibration unit 122 are illustrated on the right side.

As illustrated in FIG. 3, in the signal generation device 10b, when the gain setting value KDCO_F by the calibration unit 122 is large, centers of the frequency waveforms can be matched by the calibration, but the modulation width of the frequency of the output signal cannot be calibrated. Therefore, in this case, as illustrated in a lower right part of FIG. 3, the maximum value and the minimum value of the frequency modulation width exceed allowable specifications (specs), and the output signal violates the specs.

Furthermore, as illustrated in FIG. 4, in the signal generation device 10b, when the gain setting value KDCO_F by the calibration unit 122 is small, the centers of the frequency waveforms can be matched by the calibration as described above, but the modulation width of the frequency cannot be calibrated. Therefore, in this case, as illustrated in a lower right part of FIG. 4, the maximum value and the minimum value of the frequency modulation width are too small compared to the allowable specifications (specs), and the output signal violates the specs.

Therefore, under the circumstances, the inventors have reached to create the embodiment of the present disclosure. A signal generation device according to the embodiment of the present disclosure has a configuration that enables real-time calibration of a modulation width of a frequency of an output signal. Specifically, in the present embodiment, a real-time calibration unit is provided to detect a correlation between a phase error between the output of the digitally controlled oscillator 100 and the reference signal and a waveform (profile) of the reference signal in real time, and perform calibration based on the correlation. Therefore, according to the present embodiment, since calibration can be performed on the modulation width of the frequency of the output signal in real time, an output signal satisfying the specs can be obtained. Hereinafter, details of the embodiment of the present disclosure created by the inventors will be sequentially described.

### 2. Embodiment

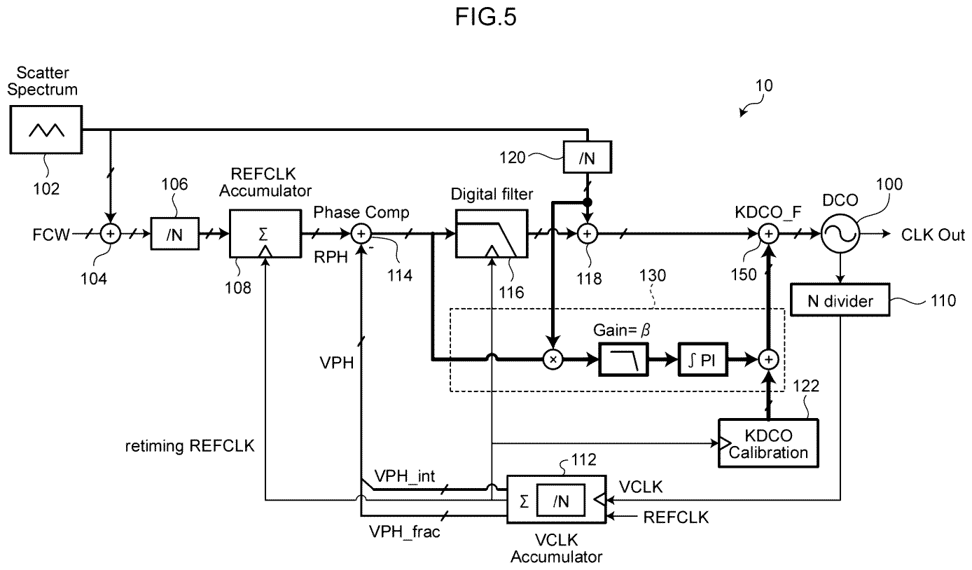

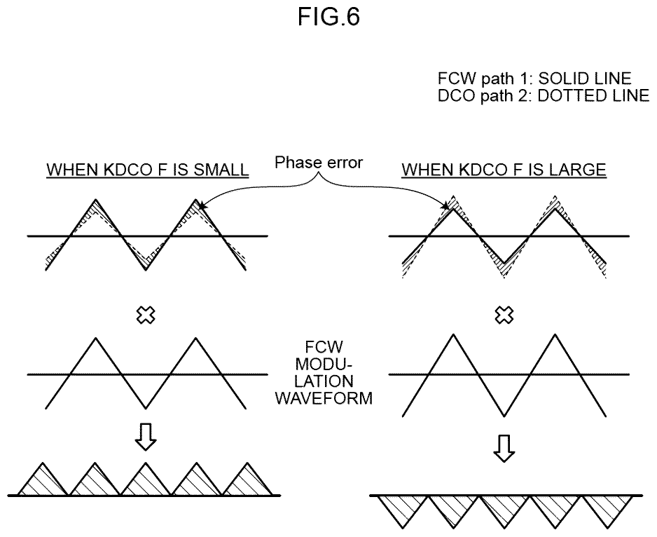

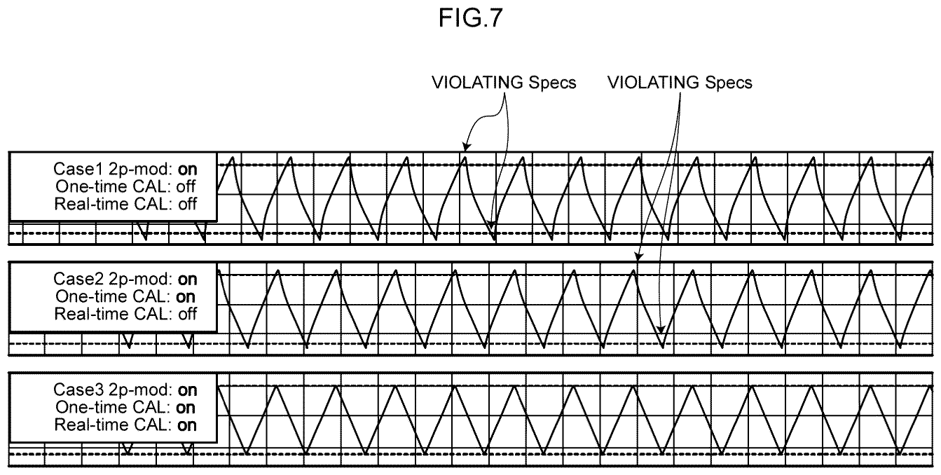

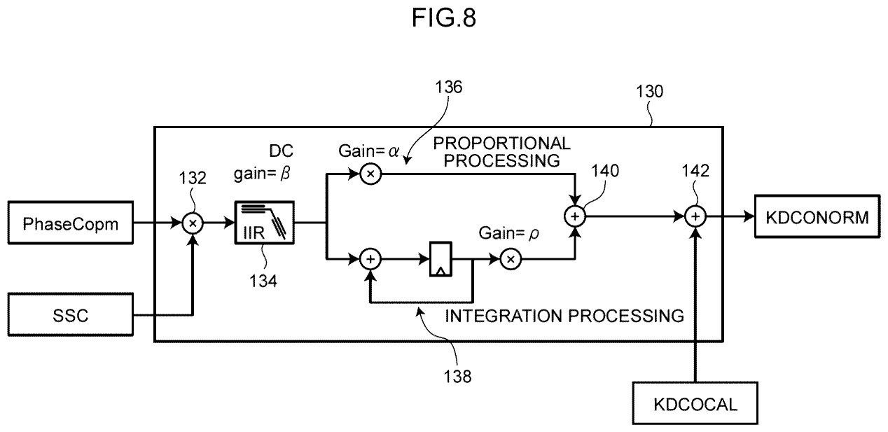

Next, details of the embodiment of the present disclosure created by the inventors will be described with reference to FIGS. 5 to 8. FIG. 5 is a diagram illustrating a circuit configuration of a signal generation device 10 according to the present embodiment, and FIG. 6 is a diagram illustrating an operation of the signal generation device 10 according to the present embodiment. FIG. 7 is a diagram illustrating a signal generated by the signal generation device 10 according to the present embodiment, and FIG. 8 is a diagram illustrating a circuit configuration of a calibration unit 130 according to the present embodiment.

First, the circuit configuration of the signal generation device 10 according to the embodiment of the present disclosure will be described with reference to FIG. 5. As illustrated in FIG. 5, the signal generation device 10 according to the present embodiment includes the calibration unit (first calibration unit) 130 as a difference from the signal generation device 10b according to the comparative example illustrated in FIG. 2. Specifically, the signal generation device 10 according to the present embodiment includes a digitally controlled oscillator 100 that performs transmission at a frequency corresponding to a set digital value. Furthermore, the signal generation device 10 includes a phase comparator 114, a digital filter (loop filter) 116, a frequency divider 110, and an accumulator 112 configuring a phase-locked loop circuit. The signal generation device 10 has a path from an SSC 102 to the phase comparator 114 via an adder 104, a frequency divider 106, and an accumulator 108. Furthermore, the signal generation device 10 has a path from the SSC 102 to the digitally controlled oscillator 100 via a frequency divider 120 without passing through the digital filter 116. In the signal generation device 10 according to the present embodiment, a path restricted by the digital filter 116 and a direct path reaching the digitally controlled oscillator 100 without passing through the digital filter 116 are coupled in an adder 118 and reach the digitally controlled oscillator 100. In addition, similarly to the signal generation device 10b according to the comparative example, the signal generation device 10 includes a calibration unit (second calibration unit) 122. Furthermore, the present embodiment includes the calibration unit 130 that detects the correlation between the phase error between the output of the digitally controlled oscillator 100 and the reference signal and the waveform (profile) of the reference signal in real time, and performs calibration based on the correlation. The calibration unit 130 and the calibration unit 122 are coupled to the digitally controlled oscillator 100 in an adder 150 to realize gain calibration of the digitally controlled oscillator 100.

The circuit configuration illustrated in FIG. 5 will be described from the left side of FIG. 5. Specifically, since a harmonic frequency generated from a clock fundamental frequency having a single frequency generated by a crystal oscillator or the like has a peak of a sharp spectrum, EMI may occur depending on an electronic apparatus. Therefore, in the SSC 102, a spectrum peak is dispersed by slightly changing a clock cycle of each clock to reduce the height thereof, and a spread spectrum clock signal is output. In the adder 104, a frequency of the spread spectrum clock signal is controlled by a frequency command word (FCW) to generate a triangular reference signal. The FCW is a parameter that specifies a ratio of a frequency of the reference signal that is output to a frequency of the spread spectrum clock signal that is input. Further, the reference signal is input to the accumulator 108 via the frequency divider 106. The accumulator 108 cumulatively adds a frequency digital value of the reference signal input according to a retiming clock signal, generates phase data, and outputs the phase data to the phase comparator 114.

Using the phase data input from the accumulators 108 and 112, the phase comparator 114 detects a phase error between the reference signal and the output signal of the digitally controlled oscillator 100 fed back by a loop including the frequency divider 110 and the accumulator 112, and outputs the phase error to the digital filter 116. Furthermore, the phase comparator 114 also outputs the phase error detected to the calibration unit 130 according to the present embodiment without passing through the digital filter 116. The digital filter 116 removes noise from the phase error in synchronization with the retiming clock signal and outputs the phase error to the adder 118. Further, the adder 118 is coupled with a path that directly gives the spread spectrum clock signal from the SSC 102 to the digitally controlled oscillator 100 via the frequency divider 120.

Still more, the output signal from the digitally controlled oscillator 100 is frequency-divided by the frequency divider 110 and input to the accumulator 112. The accumulator 112 cumulatively adds the frequency digital value of the output signal that is input, according to the reference clock signal, generates phase data, and provides a feedback input to the phase comparator 114.

Furthermore, in the present embodiment, calibration is performed by the calibration unit 130 and the calibration unit 122. Specifically, in the present embodiment, the calibration unit 130 detects in real time the correlation between the phase error output from the phase comparator 114 without passing through (bypassing) the digital filter 116 and the waveform (profile) of the reference signal, and digitally processes a detection result to generate a calibration value KDCO_F_2. Furthermore, similarly to the comparative example, the calibration unit 122 performs calibration so as to match the gain between a path (first path) including the phase-locked loop circuit from the phase comparator 114 to the digitally controlled oscillator 100 via the digital filter 116 and a direct path (second path) from the SSC 102 to the digitally controlled oscillator 100 without passing through the digital filter 116. Specifically, similarly to the comparative example, the calibration unit 122 generates the calibration value KDCO_F_1 for adjusting the gain based on the output signal of the digitally controlled oscillator 100. Furthermore, in the present embodiment, a gain setting value KDCO_F is generated by adding the calibration value KDCO_F_1 by the calibration unit 122 and the calibration value KDCO_F_2 to calibrate the digitally controlled oscillator 100 via the adder 150.

The operation of the calibration unit 130 will be described with reference to FIG. 6. In the following description, the path 1 is a path from the SSC 102 to the phase comparator 114. In addition, the path 2 is a path from the SSC 102 to the digitally controlled oscillator 100 without passing through the digital filter 116, and from the digitally controlled oscillator 100 to the phase comparator 114 via the frequency divider 110.

As illustrated in an upper left part of FIG. 6, when the gain setting value KDCO_F is small, the signal that has passed through the path 2 has a smaller amplitude than the signal that has passed through the path 1, and a phase error occurs accordingly. Furthermore, as illustrated in an upper right part of FIG. 6, when the gain setting value KDCO_F is large, the signal that has passed through the path 2 has a larger amplitude than the signal that has passed through the path 1, and a phase error occurs accordingly. Therefore, the calibration unit 130 according to the present embodiment acquires in real time a multiplication value (hatched region illustrated in a lower part of FIG. 6) of the phase error (hatched region illustrated in the upper part of FIG. 6) output from the phase comparator 114 by bypassing the digital filter 116 and the waveform (profile) (FCW modulation waveform) (middle part of FIG. 6) of the spread spectrum clock signal output from the SSC 102 via the frequency divider 120 as a correlation (correlation result). Furthermore, the calibration unit 130 averages the multiplication values by a filter, and then performs proportional processing and an integration processing to generate the calibration value KDCO_F_2 based on an addition result of these processes. When the phase error disappears (i.e., when the phase error becomes “0” (zero) ), the multiplication value becomes 0. Even when noise is included in the multiplication value, the influence of noise can be suppressed by averaging by the filter. Note that a detailed configuration of the calibration unit 130 will be described later.

In the present embodiment, not only the calibration of the offset (DC) variation (drift) of the output signal due to temperature, power supply voltage, or the like by the calibration unit 122 but also a drift of the modulation width of the frequency of the output signal due to temperature, power supply voltage, or the like by the calibration unit 130 can be calibrated in real time. As a result, according to the present embodiment, even when there is a fluctuation in temperature, power supply voltage, or the like, the output signal can satisfy required specifications (specs).

Effects of the present embodiment will be described with reference to FIG. 7. Specifically, an upper part of FIG. 7 illustrates a frequency waveform, obtained by simulation, of the output signal in the two-point signal generation device not provided with the calibration unit 122 and the calibration unit 130. Still more, a middle part of FIG. 7 illustrates a frequency waveform, obtained by simulation, of the output signal in the two-point signal generation device 10b provided with only the calibration unit 122. Furthermore, a lower part of FIG. 7 illustrates a frequency waveform, obtained by simulation, of the output signal in the two-point signal generation device 10 provided with the calibration unit 122 and the calibration unit 130 (note that the gain described here is a gain (ρ) of an integration processing unit of the calibration unit 130). From the frequency waveforms illustrated in the upper part and the middle part of FIG. 7, it can be seen that the maximum value and the minimum value of the frequency modulation width exceed the allowable specifications (specs) in the two-point signal generation device not including the calibration unit 130, and thus the output signal is violating the specs. On the other hand, from the frequency waveform illustrated in the lower part of FIG. 7, it can be seen that the maximum value and the minimum value of the frequency modulation width are within the allowable specifications (specs) in the two-point signal generation device 10 including the calibration unit 130, and thus the output signal satisfies the specs. Note that, in the present embodiment, it is not essential to perform the one-time calibration by the calibration unit 122, but as illustrated in the frequency waveform in the lower part of FIG. 7, it is possible to perform the calibration and the synchronization of the output signal more quickly by combining the one-time calibration by the calibration unit 122 and the real-time calibration by the calibration unit 130. In other words, when both are combined, the output signal becomes close to a target value by the one-time calibration by the calibration unit 122, and then the output signal becomes the target value by the real-time calibration by the calibration unit 130.

Next, a detailed configuration of the calibration unit 130 according to the present embodiment will be described with reference to FIG. 8.

As illustrated in FIG. 8, the calibration unit 130 includes a multiplier (multiplication unit) 132 that multiplies the phase error output from the phase comparator 114 by the waveform (profile) (FCW modulation waveform) of the spread spectrum clock signal output from the SSC 102 via the frequency divider 120. Note that the spread spectrum clock signal input to the multiplier 132 is assumed to be a signal obtained by delaying the spread spectrum clock signal input to the accumulator 108 by one cycle. Further, the multiplier 132 outputs a multiplication result to an infinite impulse response filter (IIR) (second infinite impulse response filter) 134. The IIR 134 can perform averaging (signal averaging) of multiplication results. Furthermore, a band and a gain (B) of the IIR 134 can be controlled by an input from the outside. Values of the band and the gain are appropriately set so that the loop is stabilized.

Furthermore, the IIR 134 outputs an averaged multiplication result to a proportional processing unit 136 and an integration processing unit 138. In other words, in the example in FIG. 8, the IIR 134 is provided between the multiplier 132, and the proportional processing unit 136 and the integration processing unit 138. In the present embodiment, the calibration unit 130 is configured to perform feedback control by two that are deviation (proportion) between the output value and the target value, and integration of the deviation. In the present embodiment, with the above configuration of the calibration unit 130, calibration can be appropriately performed following the phase error detected in real time. Note that, in the present embodiment, a differentiation processing unit (not illustrated) that performs control by differentiation of the deviation may be added to the proportional processing unit 136 and the integration processing unit 138. Furthermore, in the present embodiment, a gain (α) of the proportional processing unit 136 and a gain (ρ) of the integration processing unit 138 can also be controlled independently of each other by an input from the outside. Values of these gains are appropriately set so that the loop is stabilized.

Furthermore, control parameters generated by the proportional processing unit 136 and the integration processing unit 138 are added by an adder (addition unit) 140 to generate the calibration value KDCO_F_2. Furthermore, an adder 142 adds the calibration value KDCO_F_1 by the calibration unit 122 to the calibration value KDCO_F_2 to generate the gain setting value KDCO_F.

Note that the digital filter 116 and the IIR 134 are preferably designed to have different bands in consideration of noise such as a temperature, a voltage fluctuation (drift) gradient, and a spread spectrum clock signal and in order to stabilize the loop (to suppress oscillation). In general, since the spread spectrum clock signal fluctuates (drifts) slowly by temperature or voltage, the bandwidth of the IIR 134 is preferably narrower than that of the digital filter 116.

Furthermore, in the embodiment of the present disclosure, the signal generation device 10 and the calibration unit 130 are not limited to the configurations illustrated in FIGS. 5 and 8, and can be variously modified.

### 3. Modifications

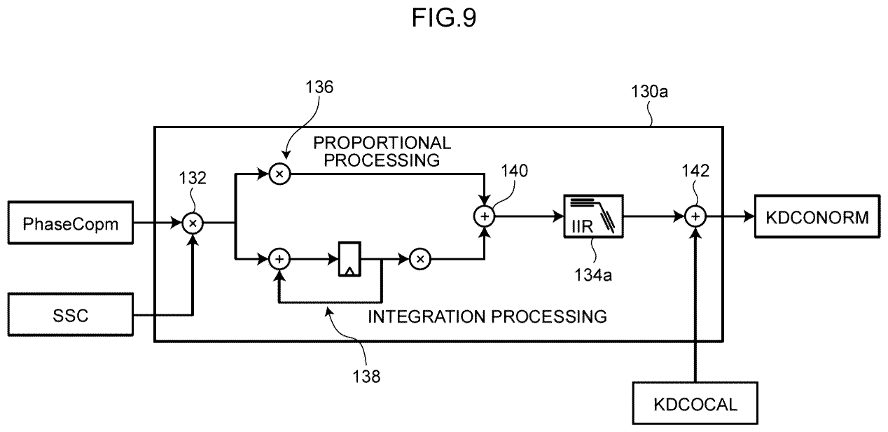

Next, configuration examples of the calibration unit 130 will be described as modifications of the present embodiment with reference to FIGS. 9 to 13. FIGS. 9 to 13 are diagrams illustrating a circuit configuration of calibration units 130a, 130b, 130c, 130d, and 130e according to the modifications of the present embodiment.

In an example illustrated in FIG. 9, the calibration unit 130a includes an IIR 134a. As compared with the example in FIG. 8, the IIR 134a is provided after the adder 140, i.e., between the adder 140 and the adder 142, instead of being provided between the multiplier 132, and the proportional processing unit 136 and the integration processing unit 138. In the example illustrated in FIG. 9, since the number of bits of the IIR 134a can be reduced by arranging the IIR 134a at the rear as compared with the example in FIG. 8, power consumption can be reduced.

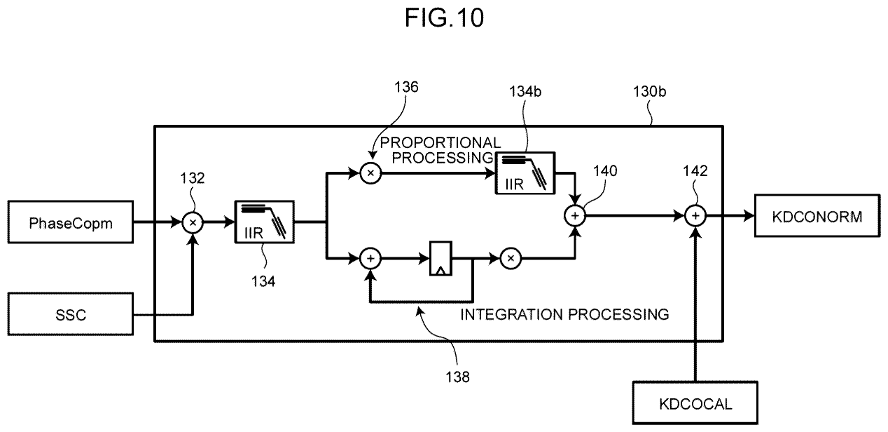

Still more, in the example illustrated in FIG. 10, the calibration unit 130b may further include an IIR 134b provided for the proportional processing unit 136 in addition to the IIR 134 provided between the multiplier 132, and the proportional processing unit 136 and the integration processing unit 138. Specifically, the IIR 134b is provided between the proportional processing unit 136 and the adder 142.

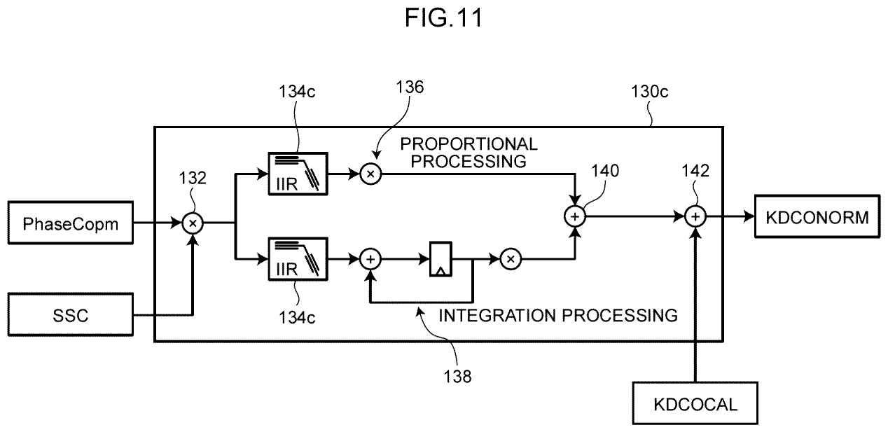

In the example illustrated in FIG. 11, the calibration unit 130c includes an IIR 134c. The IIR 134c may be provided for each of the proportional processing unit 136 and the integration processing unit 138 instead of being provided between the multiplier 132, and the proportional processing unit 136 and the integration processing unit 138. By providing the IIR 134c for each, the design of each IIR 134c can be matched to the proportional processing unit 136 and the integration processing unit 138. As a result, design freedom can be increased. Specifically, in the example illustrated in FIG. 11, each IIR 134c is provided between the multiplier 132 and the proportional processing unit 136, and between the multiplier 132 and the integration processing unit 138.

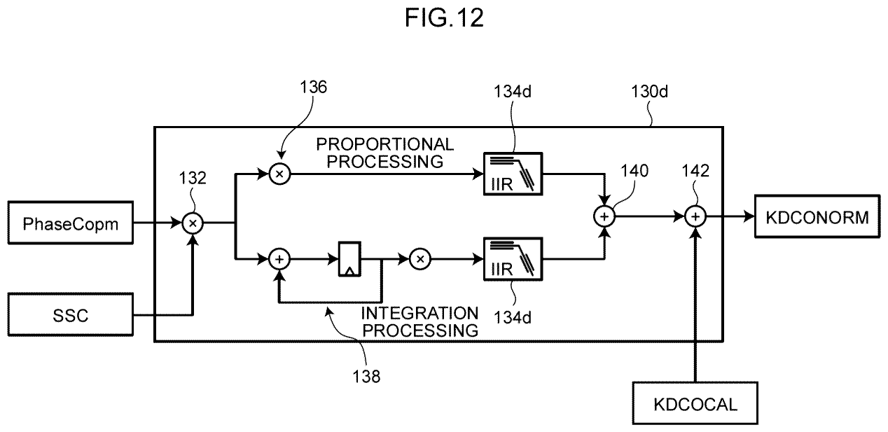

Still more, also in the example illustrated in FIG. 12, an IIR 134d may be provided for each of the proportional processing unit 136 and the integration processing unit 138 instead of being provided between the multiplier 132, and the proportional processing unit 136 and the integration processing unit 138. Specifically, each IIR 134d is provided between the proportional processing unit 136 and the adder 140, and between the integration processing unit 138 and the adder 140.

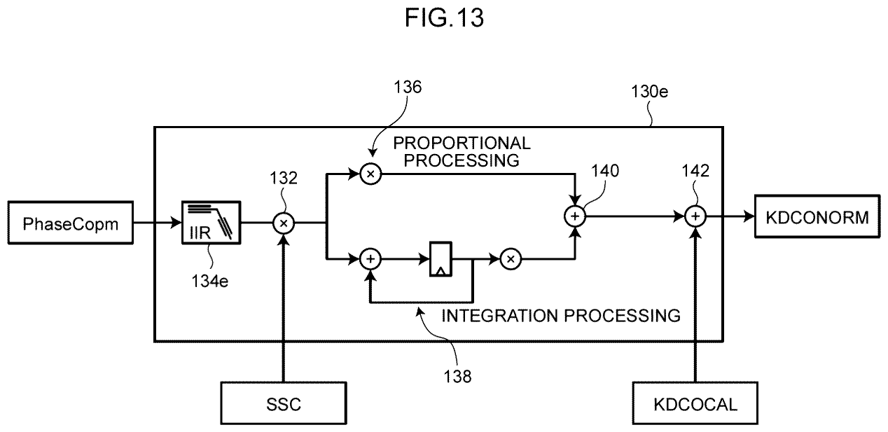

Furthermore, in the example illustrated in FIG. 13, an IIR (first infinite impulse response filter) 134e may be provided in front of the multiplier 132 instead of being provided between the multiplier 132, and the proportional processing unit 136 and the integration processing unit 138. In this case, the phase error averaged by the IIR 134e is input to the multiplier 132. As described above, in the calibration unit 130e, since a bit width of the IIR 134e can be narrowed by providing the IIR 134e in front of the multiplier 132, a circuit scale and power consumption can be reduced. In particular, when high-speed operation is desired, power consumption can be effectively reduced.

Note that, in the modifications of the embodiment of the present disclosure, the calibration unit 130 is not limited to the configurations illustrated in FIGS. 9 to 13, and can be modified in various ways.

### 4. Summary

As described above, in the embodiment of the present disclosure, the calibration unit 130 can perform calibration in real time even when the modulation width of the frequency of the output signal is drifted due to the temperature, the power supply voltage, or the like. As a result, according to the present embodiment, even when there is a fluctuation in temperature, power supply voltage, or the like, the output signal can satisfy required specifications (specs).

### 5. Imaging Device

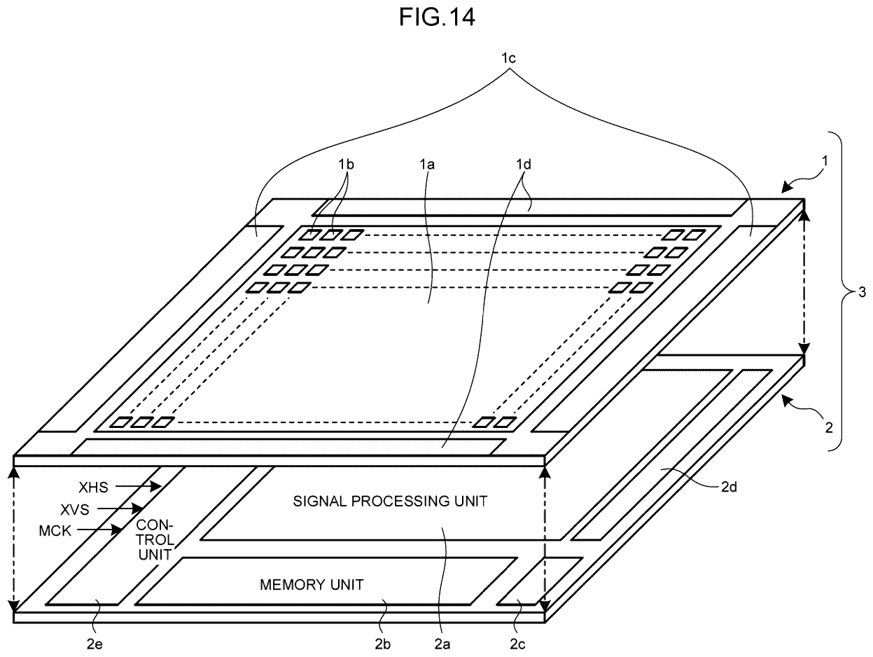

Next, a schematic configuration of an imaging device to which the signal generation device 10 according to the present embodiment can be applied will be described with reference to FIG. 14. FIG. 14 is a diagram illustrating an example of a schematic configuration of an imaging device 3 to which the signal generation device 10 according to the present embodiment can be applied. The clock signal generated by the signal generation device 10 according to the present embodiment is used in various places of the imaging device 3.

The imaging device 3 illustrated in FIG. 14 is a complementary metal oxide semiconductor (CMOS) image sensor. The imaging device 3 includes stacked semiconductor chip 1 and semiconductor chip 2.

The semiconductor chip 1 is a pixel chip. In the semiconductor chip 1, a pixel array section 1a (pixel unit) is formed. The pixel array section 1a includes a plurality of pixels 1b arranged two-dimensionally. Each pixel 1b includes a photoelectric conversion element (imaging element) (not illustrated). A pad section 1c and a via section 1d are provided in a peripheral edge of the semiconductor chip 1. The pad section 1c is used for electrical connection between the semiconductor chip 1 and an outside of the semiconductor chip 1. The via section 1d is used for electrical connection between the semiconductor chip 1 and the semiconductor chip 2. For example, a pixel signal (here, an analog signal) read from each pixel 1b is transmitted to the semiconductor chip 2 via the via section 1d. In the example illustrated in FIG. 14, the pad section 1c is a pair of pad sections provided on both sides of the pixel array section 1a. The via section 1d is a pair of via sections provided on both sides of the pixel array section 1a. Note that a configuration in which a pad section is provided on the semiconductor chip 2, and the semiconductor chip 1 is opened to be bonded to a pad on a semiconductor chip 2 side, a configuration in which the semiconductor chip 2 is electrically connected via a through silicon via (TSV), or the like can also be applied to the imaging device 3.

The semiconductor chip 2 may be a circuit chip. In the semiconductor chip 2, peripheral circuit units such as a signal processing unit 2a, a memory unit 2b, a data processing unit 2c, an interface unit 2d, and a control unit 2e are formed in addition to a drive unit (not illustrated) that drives each pixel 1b. Power from a power supply (not illustrated in FIG. 14) is supplied to each circuit.

The signal processing unit 2a processes the pixel signal of each pixel 1b. Processing includes analog digital (AD) conversion and the like. The memory unit 2b stores the pixel signal (pixel data) processed by the signal processing unit 2a. The data processing unit 2c sequentially reads the pixel data stored in the data processing unit 2c and sends the pixel data to the interface unit 2d. The interface unit 2d may be a high-speed interface that outputs pixel data to the outside of the semiconductor chip 2 in a format according to a given standard.

The control unit 2e controls the operations of the drive unit (not illustrated), the signal processing unit 2a, the memory unit 2b, the data processing unit 2c, the interface unit 2d, and the like described above in synchronization with circuits (the pixel array section 1a and the like) of the semiconductor chip 1 based on reference clocks given such as a horizontal synchronization signal XHS, a vertical synchronization signal XVS, and a master clock MCK. The control unit 2e can also control the signal generation device 10 according to the present embodiment.

In the semiconductor chip 1 having a stacked structure of the semiconductor chip 1 and the semiconductor chip 2, the semiconductor chip 1 can be brought close to the size (area) of the pixel array section 1a, and thus the size of an entire semiconductor chip can be reduced. Still more, since a process suitable for forming the pixel 1b can be applied to the semiconductor chip 1 and a process suitable for forming a peripheral circuit such as the signal processing unit 2a can be applied to the semiconductor chip 2, the processes can be optimized.

A peripheral circuit portion including the signal processing unit 2a that performs processing such as AD conversion is configured on the semiconductor chip 2 (on the same substrate), thereby implementing high-speed processing. When digital data transmission is performed between separate semiconductor chips, there is a possibility that a clock delay occurs due to an influence of parasitic capacitance or the like, which hinders high-speed processing, but such a problem does not occur.

Furthermore, for example, the reference clocks supplied to the signal processing unit 2a that performs the AD conversion processing, the interface unit 2d, the control unit 2e, and the like can be supplied from the signal generation device 10 according to the present embodiment mounted on the imaging device 3. The reference clocks used in the imaging device 3 are required to have a wide range of frequencies. A signal generation device that outputs the reference clocks having a wide frequency has a configuration that is easily affected by temperature or power supply fluctuation. Therefore, by applying the present embodiment, the output signal can easily satisfy required specifications (specs) even when there is a fluctuation in temperature, power supply voltage, or the like. For example, the signal generation device 10 according to the present embodiment can be formed on the semiconductor chip 2.

Note that the present embodiment is not limited to being applied to the imaging device 3, and can also be applied to other electronic apparatuses such as a communication device, a detection device equipped with various sensors, and the like.

### 6. Electronic Apparatus

### 6.1 Example of Application to Camera

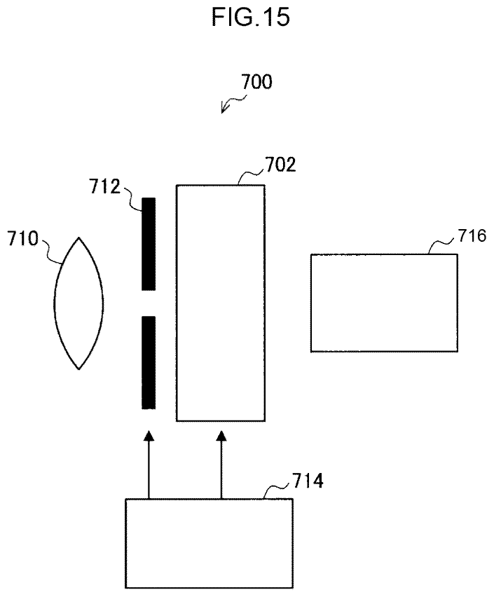

The technology according to the present disclosure (present technology) can be further applied to various products. For example, the technology according to the present disclosure may be applied to a camera. Therefore, a configuration example of a camera 700 as an electronic apparatus to which the present technology is applied will be described with reference to FIG. 15. FIG. 15 is a diagram illustrating an example of a schematic functional configuration of the camera 700 to which the technology according to the present disclosure (present technology) can be applied.

As illustrated in FIG. 17, the camera 700 includes an imaging device 702, an optical lens 710, a shutter mechanism 712, a drive circuit unit 714, and a signal processing circuit unit 716. The optical lens 710 forms an image of image light (incident light) from a subject on an imaging surface of the imaging device 702. As a result, a signal charge is accumulated in an imaging element (not illustrated) of the imaging device 702 for a certain period. The shutter mechanism 712 opens and closes to control a light irradiation period and a light shielding period for the imaging device 702. The drive circuit unit 714 supplies a drive signal for controlling a signal transfer operation of the imaging device 702, a shutter operation of the shutter mechanism 712, and the like to the imaging device 702 and the shutter mechanism 712. In other words, the imaging device 702 performs signal transfer based on the drive signal (timing signal) supplied from the drive circuit unit 714. The signal processing circuit unit 716 performs various types of signal processing. For example, the signal processing circuit unit 716 outputs a video signal subjected to signal processing to, for example, a storage medium (not illustrated) such as a memory, or to a display section (not illustrated). For example, in the drive circuit unit 714 or the signal processing circuit unit 716, the technology according to the present disclosure (present technology) can be applied to generate a clock signal for generating the drive signal or performing signal processing.

### 6.2 Example of Application to Smartphone

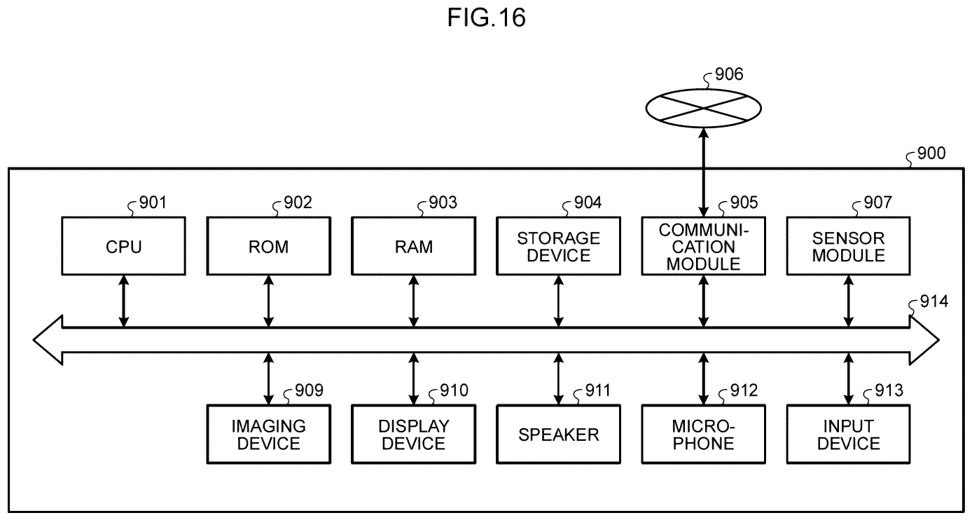

For example, the technology according to the present. disclosure may be applied to a smartphone. Therefore, a configuration example of a smartphone 900 as an electronic apparatus to which the present technology is applied will be described with reference to FIG. 16. FIG. 16 is a block diagram illustrating an example of schematic functional configuration of the smartphone 900 to which the technology according to the present disclosure (present technology) can be applied.

As illustrated in FIG. 16, the smartphone 900 includes a central processing unit (CPU) 901, a read only memory (ROM) 902, and a random access memory (RAM) 903. In addition, the smartphone 900 includes a storage device 904, a communication module 905, and a sensor module 907. Furthermore, the smartphone 900 includes an imaging device 909, a display device 910, a speaker 911, a microphone 912, an input device 913, and a bus 914. Furthermore, the smartphone 900 may include a processing circuit such as a digital signal processor (DSP) instead of or in addition to the CPU 901.

The CPU 901 functions as an arithmetic processing device and a control device, and controls the overall operation in the smartphone 900 or a part thereof according to various programs recorded in the ROM 902, the RAM 903, the storage device 904, or the like. The ROM 902 stores programs, operation parameters, and the like used by the CPU 901. The RAM 903 primarily stores programs used in the execution of the CPU 901, parameters that appropriately change in the execution, and the like. The CPU 901, the ROM 902, and the RAM 903 are connected to one another by the bus 914. In addition, the storage device 904 is a device for data storage configured as an example of a storage unit of the smartphone 900. The storage device 904 includes, for example, a magnetic storage device such as a hard disk drive (HDD), a semiconductor storage device, and an optical storage device. The storage device 904 stores programs and various data executed by the CPU 901, various data acquired from the outside, and the like.

The communication module 905 is a communication interface including, for example, a communication device for connecting to the communication network 906. The communication module 905 can be, for example, a communication card for wired or wireless local area network (LAN), Bluetooth (registered trademark), wireless USB (WUSB), or the like. Furthermore, the communication module 905 may be a router for optical communication, a router for asymmetric digital subscriber line (ADSL), a modem for various types of communication, or the like. The communication module 905 transmits and receives signals and the like to and from the Internet and other communication devices using a predetermined protocol such as transmission control protocol (TCP)/Internet protocol (IP). Furthermore, the communication network 906 connected to the communication module 905 is a network connected in a wired or wireless manner, and is, for example, the Internet, a home LAN, infrared communication, or satellite communication.

The sensor module 907 includes, for example, various sensors such as a motion sensor (e.g., acceleration sensor, gyro sensor, and geomagnetic sensor), a biological information sensor (e.g., pulse sensor, blood pressure sensor, and fingerprint sensor), or a position sensor (e.g., global navigation satellite system (GNSS) receiver). For example, the technology according to the present disclosure (present technology) can be applied to generate a clock signal for controlling the sensor module 907.

The imaging device 909 is provided on the surface of the smartphone 900 and can capture an image of an object or the like located on a back side or a front side of the smartphone 900, and the technology according to the present disclosure (present technology) can be applied to the imaging device 909. Specifically, the imaging device 909 can include a CMOS (imaging element (not illustrated)) such as an image sensor, and a signal processing circuit (not illustrated) that performs imaging signal processing on a signal photoelectrically converted by the imaging element. Furthermore, the imaging device 909 may further include an optical system mechanism (not illustrated) including an imaging lens, a zoom lens, and a focus lens, and a drive system mechanism (not illustrated) that controls the operation of the optical system mechanism. Then, the imaging element collects incident light from an object as an optical image, and the signal processing circuit photoelectrically converts the formed optical image in units of pixels, reads a signal of each pixel as an imaging signal, and performs image processing to acquire a captured image.

The display device 910 is provided on the surface of the smartphone 900, and can be, for example, a display device such as a liquid crystal display (LCD) or an organic electro luminescence (EL) display. The display device 910 can display an operation screen, the captured image acquired by the above-described imaging device 909, and the like.

The speaker 911 can output, for example, a call voice, a voice accompanying video content displayed by the display device 910 described above, and the like to the user.

The microphone 912 can collect, for example, a call voice of the user, a voice including a command to activate a function of the smartphone 900, and a voice in a surrounding environment of the smartphone 900.

The input device 913 is a device operated by the user, such as a button, a keyboard, a touch panel, or a mouse. The input device 913 includes an input control circuit that generates an input signal based on information input by the user and outputs the input signal to the CPU 901. By operating the input device 913, the user can input various data to the smartphone 900 and give an instruction on the processing operation.

The configuration example of the smartphone 900 has been described above. Each of the above-described Components may be configured using a general-purpose member, or may be configured by hardware specialized for the function of each component. This configuration can be appropriately changed according to a technical level at the time of implementation.

### 7. Supplement

Although the preferred embodiments of the present disclosure have been described in detail with reference to the accompanying drawings, the technical scope of the present disclosure is not limited to these examples. It is obvious that a person having ordinary knowledge in the technical field of the present disclosure can conceive various changes or modifications within the scope of the technical idea described in the claims, and it is naturally understood that these also belong to the technical scope of the present disclosure.

Furthermore, the effects described in the present specification are merely illustrative or exemplary, and are not restrictive. In other words, the technology according to the present disclosure can exhibit other effects obvious to those skilled in the art from the description of the present specification in addition to or instead of the above effects.

The present technology may also have the following configurations.

(1) A signal generation device comprising:
a digitally controlled oscillator;
a first path including a phase-locked loop that detects a phase error between an output of the digitally controlled oscillator and a reference signal, and performs feedback control of the digitally controlled oscillator via a loop filter;
a second path that controls the digitally controlled oscillator based on the reference signal without passing through the loop filter; and
a first calibration unit that performs calibration in real time on the digitally controlled oscillator based on a correlation between the phase error and a waveform of the reference signal.

(2) The signal generation device according to (1), wherein
the first calibration unit includes a multiplication unit that multiplies the phase error by the waveform of the reference signal and acquires a correlation result indicating a correlation between the phase error and the reference signal, and
the first calibration unit calibrates the digitally controlled oscillator based on the correlation result.

(3) The signal generation device according to (1), wherein
the first calibration unit includes:
   a first infinite impulse response filter that performs signal averaging, and
   a multiplication unit that multiplies the phase error averaged by the first infinite impulse response filter by the waveform of the reference signal, and acquires a correlation result indicating a correlation between the phase error and the reference signal, and
the first calibration unit calibrates the digitally controlled oscillator based on the correlation result.

(4) The signal generation device according to (2) or (3), wherein
the first calibration unit includes:
   a proportional processing unit that performs proportional processing on the correlation result,
   an integration processing unit that performs integration processing on the correlation result, and
   an addition unit that adds a result of the proportional processing and a result of the integration processing unit, and
the first calibration unit calibrates the digitally controlled oscillator based on an addition result of the addition unit.

(5) The signal generation device according to (4), wherein
the first calibration unit includes a second infinite impulse response filter that performs signal averaging.

(6) The signal generation device according to (5), wherein
the second infinite impulse response filter is provided between the multiplication unit, and the proportional processing unit and the integration processing unit.

(7) The signal generation device according to (5), wherein
the second infinite impulse response filter is provided after the addition unit.

(8) The signal generation device according to (6), wherein
the second infinite impulse response filter is further provided for the proportional processing unit.

(9) The signal generation device according to (8), wherein
the second infinite impulse response filter is provided between the proportional processing unit and the addition unit.

(10) The signal generation device according to (5), wherein
the second infinite impulse response filter is provided for each of the proportional processing unit and the integration processing unit.

(11) The signal generation device according to (10), wherein
the second infinite impulse response filter is provided between the multiplication unit and the proportional processing unit or the integration processing unit.

(12) The signal generation device according to (10), wherein
the second infinite impulse response filter is provided between the proportional processing unit or the integration processing unit and the addition unit.

(13) The signal generation device according to (1), further comprising a second calibration unit that performs gain calibration on the digitally controlled oscillator at the time of starting so as to match a gain of the first path with a gain of the second path.

(14) The signal generation device according to (1), wherein
the phase-locked loop includes:
   a phase comparator that detects the phase error,
   a digital filter that outputs the phase error to the digitally controlled oscillator, and
   a frequency divider that frequency-divides an output of the digitally controlled oscillator, and provides a feedback input to the phase comparator.

(15) An imaging device comprising:
a plurality of imaging elements that detect light;
a signal processing unit that performs processing on an output signal from the plurality of imaging elements;
a control unit that controls the plurality of imaging elements; and
a signal generation device that outputs a reference clock signal to the signal processing unit and the control unit, wherein
the signal generation device includes:
   a digitally controlled oscillator,
   a first path including a phase-locked loop that detects a phase error between an output of the digitally controlled oscillator and a reference signal, and performs feedback control of the digitally controlled oscillator via a loop filter,
   a second path that controls the digitally controlled oscillator based on the reference signal without passing through the loop filter, and
   a first calibration unit that performs calibration in real time on the digitally controlled oscillator based on a correlation between the phase error and a waveform of the reference signal.

(16) An electronic apparatus provided with a signal generation device, wherein
the signal generation device includes:
   a digitally controlled oscillator,
   a first path including a phase-locked loop that detects a phase error between an output of the digitally controlled oscillator and a reference signal, and performs feedback control of the digitally controlled oscillator via a loop filter,
   a second path that controls the digitally controlled oscillator based on the reference signal without passing through the loop filter, and
   a first calibration unit that performs calibration in real time on the digitally controlled oscillator based on a correlation between the phase error and a waveform of the reference signal.

### REFERENCE SIGNS LIST

1, 2 SEMICONDUCTOR CHIP
1a PIXEL ARRAY SECTION
1b PIXEL
1c PAD SECTION
1d VIA SECTION
2a SIGNAL PROCESSING UNIT
2b MEMORY UNIT
2c DATA PROCESSING UNIT
2d INTERFACE UNIT
2e CONTROL UNIT
3, 702, 909 IMAGING DEVICE
10, 10a, 10b SIGNAL GENERATION DEVICE
100 DIGITALLY CONTROLLED OSCILLATOR
102 SSC
104, 118, 140, 142, 150 ADDER
106, 110, 120 FREQUENCY DIVIDER
108, 112 ACCUMULATOR
114 PHASE COMPARATOR
116 DIGITAL FILTER
122, 130, 130a, 130b, 130c, 130d, 130e CALIBRATION UNIT
124 GAIN NORMALIZATION UNIT
132 MULTIPLIER
134, 134a, 134b, 134c, 134d, 134e IIR
136 PROPORTIONAL PROCESSING UNIT
138 INTEGRATION PROCESSING UNIT
700 CAMERA
710 OPTICAL LENS
712 SHUTTER MECHANISM
714 DRIVE CIRCUIT UNIT
716 SIGNAL PROCESSING CIRCUIT UNIT
900 SMARTPHONE
901 CPU
902 ROM
903 RAM
904 STORAGE DEVICE
905 COMMUNICATION MODULE
906 COMMUNICATION NETWORK
907 SENSOR MODULE
910 DISPLAY DEVICE
911 SPEAKER
912 MICROPHONE
913 INPUT DEVICE
914 BUS

1. A signal generation device comprising:
a digitally controlled oscillator;
a first path including a phase-locked loop that detects a phase error between an output of the digitally controlled oscillator and a reference signal, and performs feedback control of the digitally controlled oscillator via a loop filter;
a second path that controls the digitally controlled oscillator based on the reference signal without passing through the loop filter; and
a first calibration unit that performs calibration in real time on the digitally controlled oscillator based on a correlation between the phase error and a waveform of the reference signal.

2. The signal generation device according to claim 1, wherein
the first calibration unit includes a multiplication unit that multiplies the phase error by the waveform of the reference signal and acquires a correlation result indicating a correlation between the phase error and the reference signal, and
the first calibration unit calibrates the digitally controlled oscillator based on the correlation result.

3. The signal generation device according to claim 1, wherein
the first calibration unit includes:
a first infinite impulse response filter that performs signal averaging, and
a multiplication unit that multiplies the phase error averaged by the first infinite impulse response filter by the waveform of the reference signal, and acquires a correlation result indicating a correlation between the phase error and the reference signal, and
the first calibration unit calibrates the digitally controlled oscillator based on the correlation result.

4. The signal generation device according to claim 2, wherein
the first calibration unit includes:
a proportional processing unit that performs proportional processing on the correlation result,
an integration processing unit that performs integration processing on the correlation result, and
an addition unit that adds a result of the proportional processing and a result of the integration processing unit, and
the first calibration unit calibrates the digitally controlled oscillator based on an addition result of the addition unit.

5. The signal generation device according to claim 4, wherein
the first calibration unit includes a second infinite impulse response filter that performs signal averaging.

6. The signal generation device according to claim 5, wherein
the second infinite impulse response filter is provided between the multiplication unit, and the proportional processing unit and the integration processing unit.

7. The signal generation device according to claim 5, wherein
the second infinite impulse response filter is provided after the addition unit.

8. The signal generation device according to claim 6, wherein
the second infinite impulse response filter is further provided for the proportional processing unit.

9. The signal generation device according to claim 8, wherein
the second infinite impulse response filter is provided between the proportional processing unit and the addition unit.

10. The signal generation device according to claim 5, wherein
the second infinite impulse response filter is provided for each of the proportional processing unit and the integration processing unit.

11. The signal generation device according to claim 10, wherein
the second infinite impulse response filter is provided between the multiplication unit and the proportional processing unit or the integration processing unit.

12. The signal generation device according to claim 10, wherein
the second infinite impulse response filter is provided between the proportional processing unit or the integration processing unit and the addition unit.

13. The signal generation device according to claim 1, further comprising a second calibration unit that performs gain calibration on the digitally controlled oscillator at the time of starting so as to match a gain of the first path with a gain of the second path.

14. The signal generation device according to claim 1, wherein
the phase-locked loop includes:
a phase comparator that detects the phase error,
a digital filter that outputs the phase error to the digitally controlled oscillator, and
a frequency divider that frequency-divides an output. of the digitally controlled oscillator, and provides a feedback input to the phase comparator.

15. An imaging device comprising:
a plurality of imaging elements that detect light;
a signal processing unit that performs processing on an output signal from the plurality of imaging elements;
a control unit that controls the plurality of imaging elements; and
a signal generation device that outputs a reference clock signal to the signal processing unit and the control unit, wherein
the signal generation device includes:
a digitally controlled oscillator,
a first path including a phase-locked loop that detects a phase error between an output of the digitally controlled oscillator and a reference signal, and performs feedback control of the digitally controlled oscillator via a loop filter,
a second path that controls the digitally controlled oscillator based on the reference signal without passing through the loop filter, and
a first calibration unit that performs calibration in real time on the digitally controlled oscillator based on a correlation between the phase error and a waveform of the reference signal.

16. An electronic apparatus provided with a signal generation device, wherein
the signal generation device includes:
a digitally controlled oscillator,
a first path including a phase-locked loop that detects a phase error between an output of the digitally controlled oscillator and a reference signal, and performs feedback control of the digitally controlled oscillator via a loop filter,
a second path that controls the digitally controlled oscillator based on the reference signal without passing through the loop filter, and
a first calibration unit that performs calibration in real time on the digitally controlled oscillator based on a correlation between the phase error and a waveform of the reference signal.
